(19) United States
(12) Patent Application Publication
(10) Pub. No.: US 2022/0309255 A1
(43) Pub. Date: Sep. 29, 2022

(54) SUM-OF-PRODUCTS CALCULATION APPARATUS

(71) Applicant: Egis Technology Inc., Hsinchu City (TW)

(72) Inventor: Chun Hsien Su, Hsinchu City (TW)

(73) Assignee: Egis Technology Inc., Hsinchu City (TW)

(21) Appl. No.: 17/683,357

(22) Filed: Mar. 1, 2022

Related U.S. Application Data
(60) Provisional application No. 63/162,502, filed on Mar. 17, 2021.
(60) Provisional application No. 63/278,468, filed on Nov. 11, 2021.

(30) Foreign Application Priority Data
Aug. 23, 2021 (CN) 202110970487.6
Jan. 12, 2022 (CN) 202210032449.0

(51) Int. Cl. G06G 7/14; H03M 1/14; G06G 7/16

(52) U.S. Cl. CPC G06G 7/14; H03M 1/145; G06G 7/16

(57) ABSTRACT

A sum-of-products calculation apparatus is provided. The sum-of-products calculation apparatus includes an analog-to-digital (A-to-D) conversion circuit having an encoder circuit and a plurality of inverters. Threshold voltages of the inverters are set according to classification threshold values of an activation function. The inverters generate a plurality of bit signals in response to an analog sum-of-products signal. The encoder circuit encodes the bit signals to generate a digital signal.

### CROSS-REFERENCE TO RELATED APPLICATION

This application claims the priority benefit of U.S. provisional application Ser. No. 63/162,502, filed on Mar. 17, 2021, the priority benefit of China application serial no. 202110970487.6, filed on Aug. 23, 2021, the priority benefit of U.S. provisional application Ser. No. 63/278,468, filed on Nov. 11, 2021, and the priority benefit of China application serial no. 202210032449.0, filed on Jan. 12, 2022. The entirety of each of the above-mentioned patent applications is hereby incorporated by reference herein and made a part of this specification.

### BACKGROUND

### Technical Field

The disclosure relates to a calculation apparatus. More particularly, the disclosure relates to a sum-of-products calculation apparatus.

### Description of Related Art

With the development of semiconductor technologies, various types of semiconductor apparatuses have been constantly introduced, some of which are capable of performing calculations, e.g., a sum-of-products calculation. The sum-of-products calculation is considerably useful in the field of artificial intelligence (AI).

In an analog neural network, it is often necessary to perform nonlinear conversion on the output of nodes in the previous layer, so that the analog neural network may deal with nonlinear issues. As to the implementation of circuits, the analog neural network firstly performs an analog-to-digital (A-to-D) conversion and then performs a calculation on an activation function. However, the complex activation function often requires accuracy of an A-to-D convertor, which leads to an increase in manufacturing costs or poor performance of the analog neural network.

### SUMMARY

The disclosure provides a sum-of-products calculation apparatus capable of reducing requirements for accuracy of an A-to-D converter and effectively enhancing performance of an analog neural network.

In an embodiment of the disclosure, a sum-of-products calculation apparatus including an A-to-D conversion circuit that has an encoder circuit and a plurality of inverters is provided. Threshold voltages of the inverters are set according to classification threshold values of an activation function. The inverters generate a plurality of bit signals in response to an analog sum-of-products signal. The encoder circuit encodes the bit signals to generate a digital signal.

In view of the above, the sum-of-products calculation apparatus provided in one or more embodiments of the disclosure includes the A-to-D conversion circuit having the encoder circuit and the inverters, the threshold voltages of the inverters are set according to the classification threshold values of the activation function, the inverters generate the bit signals in response to the analog sum-of-products signal, and the encoder circuit encodes the bit signals to generate the digital signal. According to the classification threshold values of the activation function, the threshold voltages of the inverters may be set, so as to complete the calculation of the activation function during the A-to-D conversion, whereby the requirements for accuracy of the A-to-D conversion circuit may be reduced, and the performance of the analog neural network may be effectively enhanced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain the principles of the disclosure.

FIG. 1 is a schematic circuit block view of a sum-of-products calculation apparatus according to an embodiment of the disclosure.

FIG. 2A is a schematic view illustrating quantitative transition points of an A-to-D converter and an activation function according to the related art.

FIG. 2B is a schematic view illustrating quantitative transition points of an A-to-D conversion circuit and an activation function according to an embodiment of the disclosure.

FIG. 3 is a schematic circuit view of an inverter according to an embodiment of the disclosure.

FIG. 4 is a schematic circuit block view of a sum-of-products calculation apparatus according to another embodiment of the disclosure.

FIG. 5 is a schematic circuit block view of a sum-of-products calculation apparatus according to another embodiment of the disclosure.

FIG. 6 is a schematic circuit block view of a control voltage generating circuit according to another embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numerals are used to represent the same drawings or similar parts in the accompanying and description, and the description of the same technical content is omitted. The description of the omitted part may be derived from the previous embodiment and will not be repeated in the following embodiments.

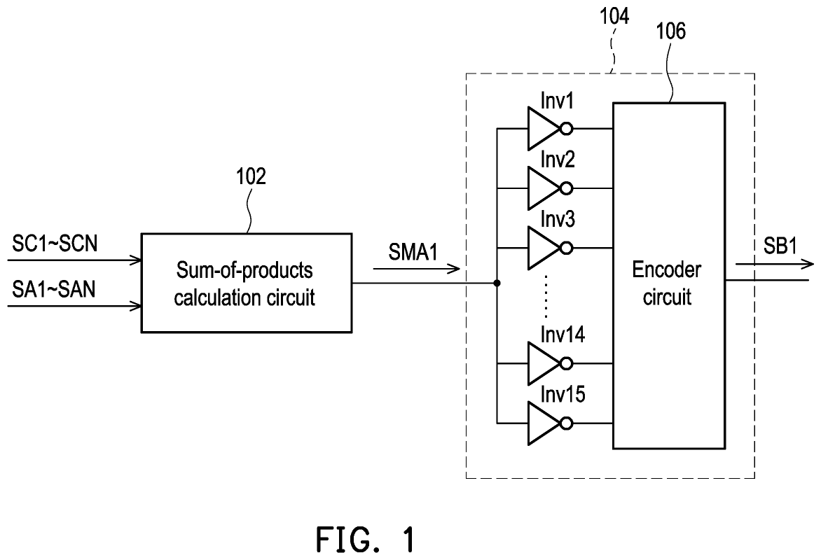

Please refer to FIG. 1, which is a schematic circuit block view of a sum-of-products calculation apparatus according to an embodiment of the disclosure. The sum-of-products calculation apparatus may be configured to perform an artificial neural network calculation and may be, for instance, an AI calculation apparatus or an edge calculation apparatus. The sum-of-products calculation apparatus includes a sum-of-products calculation circuit 102 and an A-to-D conversion circuit 104, and the sum-of-products calculation circuit 102 is coupled to the A-to-D conversion circuit 104. The sum-of-products calculation circuit 102 may perform a sum-of-products calculation on a plurality of weight signals SC1-SCN and a plurality of analog input signals SA1-SAN to output an analog sum-of-products signal SMA1, wherein N is a positive integer. The A-to-D conversion circuit 104 may convert the analog sum-of-products signal SMA1 to a digital signal SB1.

To be specific, the A-to-D conversion circuit 104 may include a plurality of inverters InV1-InV15 and an encoder circuit 106, and input terminals and output terminals of the inverters InV1-InV15 are respectively coupled to the sum-of-products calculation circuit 102 and the encoder circuit 106. Each of the inverters InV1-InV15 has a different threshold voltage which corresponds to the quantitative conversion voltages of each level of an A-to-D converter, so as to generate corresponding A-to-D output bit signals in response to the analog sum-of-products signal SMA1. For instance, in this embodiment, the threshold voltage of the inverter InV1 may serve to generate the lowest order bit signal, and the threshold voltage of the inverter InV15 may serve to generate the highest order bit signal. The bit signals generated by the inverters InV1-InV15 may, for instance, constitute a thermometer code (which should however not be construed as a limitation in the disclosure) to represent the value of the analog sum-of-products signal SMA1. In this embodiment, the threshold voltages of the inverters InV1-InV15 may be set according to classification threshold values of an activation function, so as to complete the calculation of the activation function during the A-to-D conversion, whereby the requirements for accuracy of the A-to-D converter may be reduced, and performance of an analog neural network may be effectively enhanced.

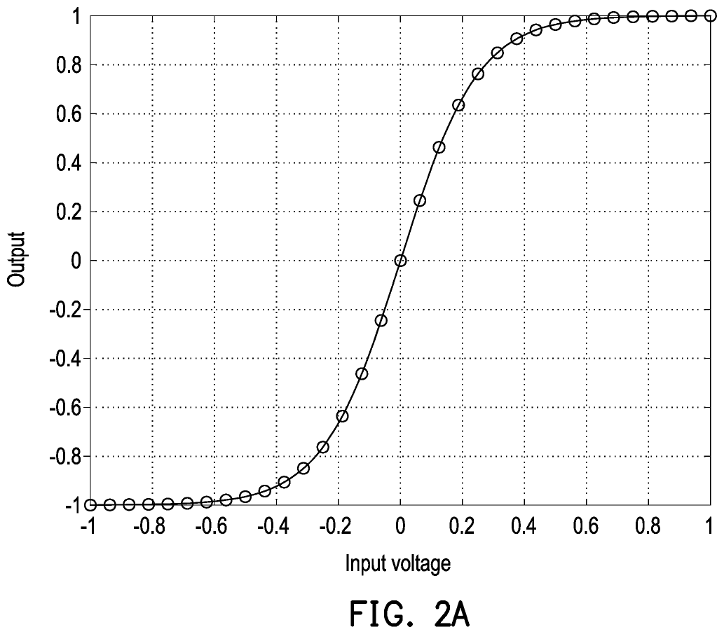

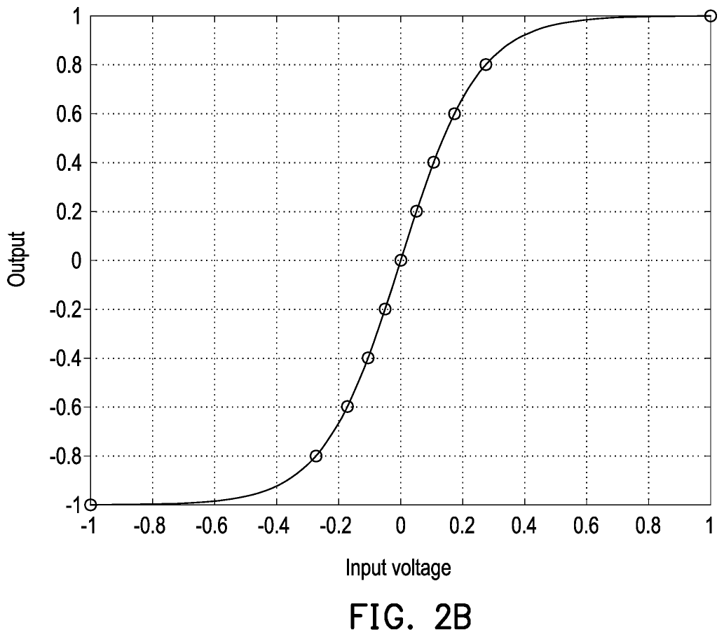

For instance, FIG. 2A is a schematic view illustrating quantitative transition points of an A-to-D converter and an activation function according to the related art. FIG. 2B is a schematic view illustrating quantitative transition points of an A-to-D conversion circuit and an activation function according to an embodiment of the disclosure. The activation function shown in FIG. 2A and FIG. 2B is a Tanh function, which should however not be construed as a limitation in the disclosure. In other embodiments, the activation function may also be any other function, such as a sigmoid function. As shown in FIG. 2A, according to the related art, the quantitative transition points of the A-to-D converter are equidistantly distributed on the horizontal axis (input voltages of the A-to-D converter). In order to perform the back-end calculation of the activation function, it is necessary to use a A-to-D converter with a high-bit resolution (at least 5-bit resolution) to meet the quantitative requirements for 33 levels. In the embodiment shown in FIG. 2B, by setting the threshold voltages of the inverters InV1-InV15 according to the classification threshold values of the activation function, a nonlinear A-to-D conversion may be performed, and the quantitative transition points of the A-to-D conversion circuit 104 may be allocated onto classification points (the classification threshold values) of the activation function, so as to allow the quantitative transition points of the A-to-D conversion circuit 104 to be equidistantly distributed on the vertical axis (output voltages of the A-to-D conversion circuit 104), whereby the calculation of the activation function may be completed while the A-to-D conversion is performed. Compared with the related art depicted in FIG. 2A, in FIG. 2B, the quantitative requirements for the A-to-D converter are reduced to 11 levels, whereby the requirements for accuracy of the A-to-D converter may be effectively reduced, and the performance of the analog neural network may be effectively enhanced.

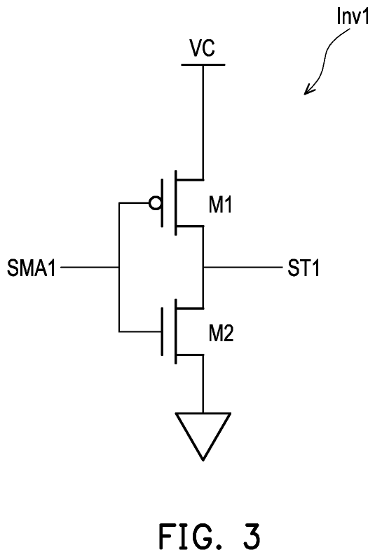

Particularly, each of the inverters InV1-InV15 may be implemented in the manner shown in FIG. 3. According to the embodiment depicted in FIG. 3, the inverter InV1 is taken to explain the implementation manner, and the inverters InV2-InV15 may be implemented in the same manner. In FIG. 3, the inverter InV1 may include a p-type transistor M1 and an n-type transistor M2, and the p-type transistor M1 and the n-type transistor M2 are coupled between an operating voltage VC and a reference voltage. In this embodiment, the reference voltage is a ground voltage, which should however not be construed as a limitation in the disclosure. Gates of the p-type transistor M1 and the n-type transistor M2 are coupled to the sum-of-products calculation circuit 102 to receive analog sum-of-products signal SMA1. A common junction point of the p-type transistor M1 and the n-type transistor M2 is coupled to the encoder circuit 106, and the inverter InV1 may generate a corresponding bit signal ST1 on the common junction point of the p-type transistor M1 and the n-type transistor M2 in response to the analog sum-of-products signal SMA1. As mentioned above, the inverters InV1-InV15 have different threshold voltages which may be set according to the classification threshold values of the activation function. In this embodiment, the threshold voltages of the inverters InV1-InV15 are different in response to different channel width-to-length ratios of the p-type transistors M1 and the n-type transistors M2. That is, the threshold voltage of each of the inverters InV1-InV15 may be determined by adjusting the channel width-to-length ratio of the p-type transistor M1 and the n-type transistor M2. For instance, the p-type transistors M1 of the inverters InV1-InV15 may have the same channel width, the n-type transistors M2 of the inverters may have the same channel width, and the threshold voltages of the inverters InV1-InV15 may be adjusted by differentiating the channel lengths of the p-type transistors M1 and the n-type transistors M2 of the inverters InV1-InV15.

In addition, the encoder circuit 106 may encode the bit signals generated by the inverters InV1-InV15 to generate the digital signal SB1. For instance, the encoder circuit 106 may encode the thermometer code constituted by the bit signals generated by the inverters InV1-InV15 into a binary signal (a 4-bit binary signal in this embodiment, which should however not be construed as a limitation in the disclosure), and the binary signal may be output as the digital signal SB1. In some embodiments, the encoder circuit 106 may be implemented, for instance, in form of a logic circuit, which should however not be construed as a limitation in the disclosure. The encoder circuit 106 may also encode the bit signals generated by the inverters InV1-InV15 into the digital signal SB1 by referring to a look-up table (e.g., a look-up table where the thermometer code is converted to a binary code).

As mentioned above, in addition to the advantages of reducing the requirements for accuracy of the A-to-D converter and enhancing the performance of the analog neural network, the sum-of-products calculation apparatus has the inverters InV1-InV15 with different threshold voltages and the encoder circuit 106 to quickly convert the analog sum-of-products signal SMA1 to the digital signal SB1; besides, it is not necessary to provide additional current or voltage, and there is no quiescent bias current but transient current. Moreover, the transient time is extremely short, thus ensuring low power consumption and high conversion efficiency. Additionally, the circuit configuration of the inverters InV1-InV15 and the encoder circuit 106 has the advantage of occupying a relatively small circuit area.

Note that the A-to-D conversion circuit 104 described in the embodiment above includes 15 inverters InV1-nV15. However, the number of inverters is not limited to what is provided in the previous embodiment, and in other embodiments, the A-to-D conversion circuit 104 may include more or fewer inverters.

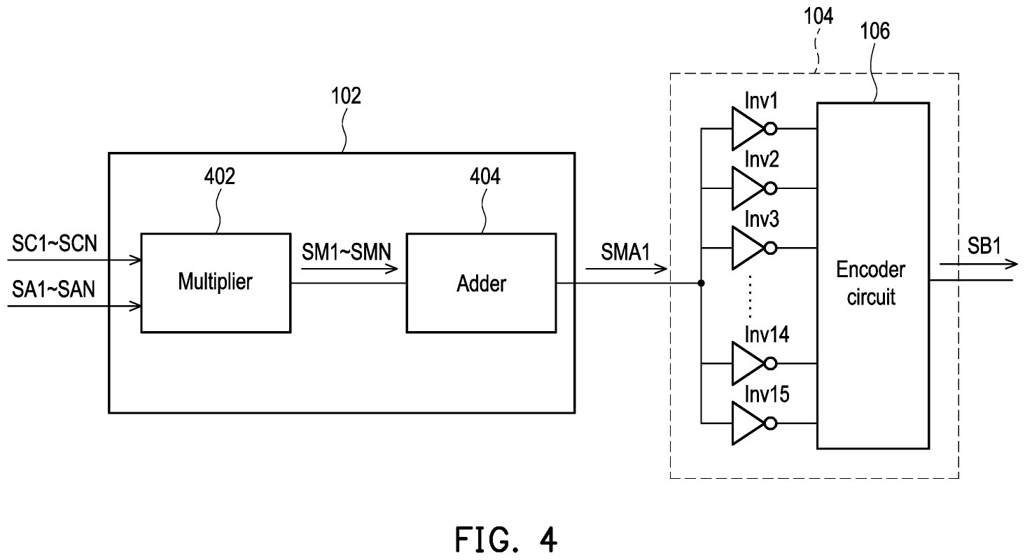

FIG. 4 is a schematic circuit block view of a sum-of-products calculation apparatus according to another embodiment of the disclosure. In particular, the sum-of-products calculation circuit 102 of the sum-of-products calculation apparatus may include a multiplier 402 and an adder 404, and the multiplier 402 is coupled to the adder 404. The multiplier 402 may receive a plurality of analog input signals SA1-SAN and a plurality of weight signals SC1-SCN, and a multiplication calculation is performed on the weight signals SC1-SCN and the analog input signals SA1-SAN to generate a plurality of product signals SM1-SMN. The adder 404 may add the product signals SM1-SMN to generate the analog sum-of-products signal SMA1.

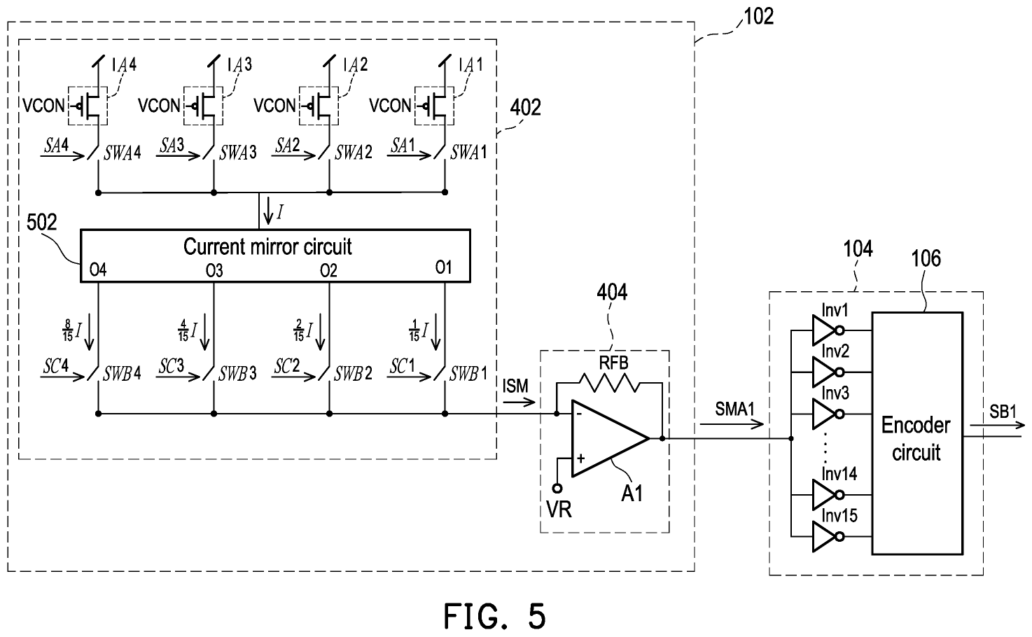

FIG. 5 is a schematic circuit block view of a sum-of-products calculation apparatus according to another embodiment of the disclosure. In this embodiment, the multiplier 402 may include a plurality of current sources IA1-IA4, switches SWA1-SWA4, a current mirror circuit 502, and switches SWB1-SWB4. The switches SWA1-SWA4 are coupled between the corresponding current sources IA1-IA4 and the current mirror circuit 502, the current mirror circuit 502 has a plurality of output terminals O1-O4, and the switches SWB1-SWB4 are coupled between the output terminals O1-O4 of the corresponding current mirror circuit 502 and a negative input terminal of a comparator A1. The adder 404 may include the comparator A1 and a feedback resistor RFB. The negative input terminal of the comparator A1 is coupled to the switches SWB1-SWB4, a positive input terminal of the comparator A1 is coupled to a reference voltage VR, an output terminal of the comparator A1 is coupled to the input terminals of the inverters InV1-InV15, and the feedback resistor RFB is coupled between the negative input terminal and the output terminal of the comparator A1.

In this embodiment, the current sources IA1-IA4 may be implemented in form of transistors, for instance, which should however not be construed as a limitation in the disclosure. The current sources IA1-IA4 may be controlled by a control voltage VCON and provide different currents, respectively; for instance, a ratio of current values of the currents provided by the current sources IA1-IA4 may be a geometric progression, e.g., the current values of the currents provided by the current sources IA1-IA4 may be 0.1 uA, 0.2 uA, 0.4 uA, and 0.8 uA in sequence, which should however not be construed as a limitation in the disclosure. The switches SWA1-SWA4 may be controlled by the analog input signals SA1-SA4 to change the state of the switches SWA1-SWA4, and the switches in an on state may provide the currents from the corresponding current sources to the current mirror circuit 502. For instance, in this embodiment, it is assumed that the switches SWA1-SWA3 are in an on state, and the switch SWA4 is in an off state; as such, the switches SWA1-SWA3 may respectively provide the currents with the current values of 0.1 uA, 0.2 uA, and 0.4 uA. That is, the current value of the current I received by the current mirror circuit 502 is 0.7 uA.

The current mirror circuit 502 may output a plurality of currents from the output terminals O1-O4 according to the currents provided by the switches SWA1-SWA3 in the on state, and the ratio of the current values of these currents may be a geometric progression. For instance, in this embodiment, the output terminals O1-O4 may output the currents with the current values of I/15, 2I/15, 4I/15, and 8I/15, respectively, which should however not be construed as a limitation in the disclosure. The switches SWB1-SWB4 may be controlled by the weight signals SC1-SC4 to change their states, and the switches in the on state may provide the currents from the corresponding output terminals to the negative input terminal of the comparator A1. For instance, in this embodiment, it is assumed that the switches SWB1 and SWB3 are in the on state, while the switches SWB2 and SWB4 are in the off state; as such, the switches SWB1 and SWB3 may respectively provide the currents with the current values of I/15 and 4I/15. That is, the current value of the current ISM received by the negative input terminal of the comparator A1 is 5I/15. After the current ISM passes through the comparator A1 and the feedback resistor RFB, the voltage output by the comparator A1 may represent the sum of products of the analog input signals SA1-SA4 and the weight signals SC1-SC4 (the analog sum-of-products signal SMA1). Note that the sum-of-products calculation circuit 102 described in this embodiment includes 4 current sources IA1-IA4, 4 switches SWA1-SWA4, and 4 switches SWB1-SWB4, while the number of the switches and the number of the current sources are not limited to what is described in this embodiment, and the relationship of the current values of the currents provided by the current sources IA1-IA4 and the relationship of the current values of the currents provided by the output terminals O1-O4 of the current mirror circuit 502 are also not limited to what is described in this embodiment.

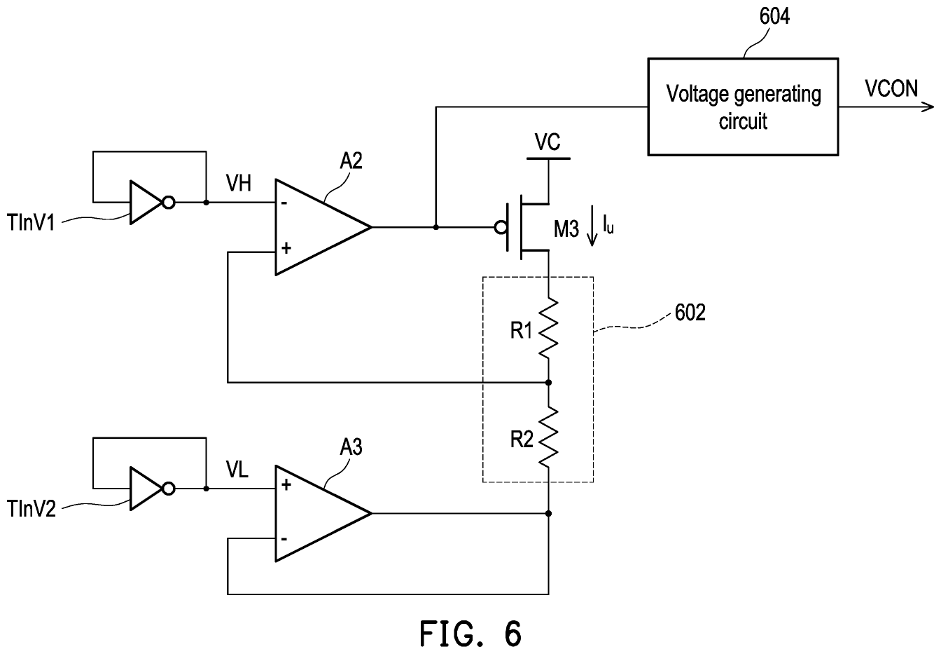

In addition, in some embodiments, the sum-of-products calculation apparatus may further include a control voltage generating circuit as shown in FIG. 6. As shown in FIG. 6, the control voltage generating circuit may include input inverters TinV1 and TinV2, comparators A2 and A3, a transistor M3, a voltage dividing circuit 602, and a voltage generating circuit 604. Input terminals and output terminals of the input inverters TinV1 and TinV2 are connected, a negative input terminal of the comparator A2 is coupled to the output terminal of the input inverter TinV1, an output terminal of the comparator A2 is coupled to a control terminal of the transistor M3, a first terminal and a second terminal of the transistor M3 are respectively coupled to the operating voltage VC and the voltage dividing circuit 602, the voltage dividing circuit 602 is further coupled to a positive input terminal of the comparator A2 and an output terminal of the comparator A3, and the voltage dividing circuit 602 may divide the voltage at the second terminal of the transistor M3 and generate a divided voltage to the positive input terminal of the comparator A2. In this embodiment, the voltage dividing circuit 602 is implemented in form of resistors R1 and R2, which should however not be construed as a limitation in the disclosure. The resistors R1 and R2 are serially connected between the second terminal of the transistor M3 and the output terminal of the comparator A3, and a common junction point of the resistors R1 and R2 is coupled to the positive input terminal of the comparator A2. A positive input terminal of the comparator A3 is coupled to the output terminal of the input inverter TinV2, and a negative input terminal and the output terminal of the comparator A3 are connected to each other. In addition, the voltage generating circuit 604 is coupled to the control terminal of the transistor M3 and control terminals of the current sources IA1-IA4 depicted in FIG. 5.

A threshold voltage of the input inverter TinV1 may be set to be greater than the threshold voltage of any of the inverters InV1-InV15, and a threshold voltage of the input inverter TinV2 may be set to be less than the threshold voltage of any of the inverters InV1-InV15. For instance, it is assumed that the threshold voltages of the inverters InV1-InV15 decrease sequentially; that is, the inverter InV1 has the maximum threshold voltage, and the inverter InV15 has the minimum threshold voltage, then the threshold voltage of the input inverter TinV1 may be set to be greater than the threshold voltage of the inverter InV1, and the threshold voltage of the input inverter TinV2 may be set to be less than the threshold voltage of the inverter InV15. For instance, the difference between the threshold voltage of the input inverter TinV1 and the threshold voltage of the inverter InV1 may be equal to the difference between the threshold voltage of the inverter InV1 and the threshold voltage of the inverter InV2, and the difference between the threshold voltage of the inverter InV15 and the threshold voltage of the input inverter TinV2 may be equal to the difference between the threshold voltage of the inverter InV14 and the threshold voltage of the inverter InV15, which should however not be construed as a limitation in the disclosure. By connecting the input terminals and the output terminals of the input inverters TinV1 and TinV2, input voltages VH and VL provided by the input inverters TinV1 and TinV2 may be equal to the threshold voltages of the input inverters TinV1 and TinV2. To be specific, for instance, the input inverters TinV1 and TinV2 may be implemented by the circuit configuration shown in FIG. 3; namely, the threshold voltage may be changed by adjusting the channel width-to-length ratios of the p-type transistors M1 and the n-type transistors M2.

The input inverters TinV1 and TinV2 may respectively provide the input voltages VH and VL to the negative input terminal of the comparator A2 and the positive input terminal of the comparator A3, so as to generate a current Iu on a conductive path of the transistor M3. The voltage generating circuit 604 may, according to the current Iu, generate a corresponding control voltage VCON to the control terminals of the current sources IA1-IA4 depicted in FIG. 5, so as to allow the current sources IA1-IA4 to provide the currents. In some embodiments, the currents provided by the current sources IA1-IA4 may be, for instance, an integer multiple of the current Iu, which should however not be construed as a limitation in the disclosure. The voltage generating circuit 604 may be implemented, for instance, in form of a current mirror circuit, which should however not be construed as a limitation in the disclosure. In addition, the input inverter TinV2 may also provide the input voltage VL as the reference voltage VR to the positive input terminal of the comparator A1 depicted in FIG. 5.

The input voltages VH and VL provided by the input inverters TinV1 and TinV2 may be dynamically changed together with circuit variables, such as temperature, process variations, circuit aging degree, and so on. Therefore, if the input inverters TinV1 and TinV2 are applied to respectively provide the input voltages VH and VL to the negative input terminal of the comparator A2 and the positive input terminal of the comparator A3 and provide the input voltage VL to the positive input terminal of the comparator A1, when other devices in the sum-of-products calculation apparatus encounter changes to the voltage operating range due to said circuit variables, the changes to the voltage operating range caused by the circuit variables may be automatically compensated. In addition, the circuit configuration of the input inverters TinV1 and TinV2 does not require any additional reference voltage and additional reference current, and the input inverters TinV1 and TinV2 have the advantages of fast response speed, favorable monotonicity, and favorable nonlinearity.

To sum up, the sum-of-products calculation apparatus provided in one or more embodiments of the disclosure includes the A-to-D conversion circuit having the encoder circuit and the inverters, the threshold voltages of the inverters may be set according to the classification threshold values of the activation function, the inverters may generate the bit signals in response to the analog sum-of-products signal, and the encoder circuit may encode the bit signals provided by the inverters to generate the digital signal. As such, based on the classification threshold values of the activation function, the threshold voltages of the inverters may be set, so as to complete the calculation of the activation function during the A-to-D conversion, whereby the requirements for the accuracy of the A-to-D conversion circuit may be reduced, and the performance of the analog neural network may be effectively enhanced.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A sum-of-products calculation apparatus, comprising:
a sum-of-products calculation circuit, performing a sum-of-products calculation on a plurality of weight signals and a plurality of analog input terminals to output an analog sum-of-products signal; and
an analog-to-digital conversion circuit, coupled to the sum-of-products calculation circuit and converting the analog sum-of-products signal into a digital signal, the analog-to-digital conversion circuit comprising:
a plurality of inverters, coupled to the sum-of-products calculation circuit, wherein threshold voltages of the inverters are set according to classification threshold values of an activation function, and the inverters generate a plurality of bit signals in response to the analog sum-of-products signal; and
an encoder circuit, coupled to the inverters and encoding the bit signals to generate the digital signal.

2. The sum-of-products calculation apparatus according to claim 1, wherein each of the inverters comprises:
a p-type transistor: and
an n-type transistor, the n-type transistor and the p-type transistor being serially connected between an operating voltage and a reference voltage, wherein a gate of the p-type transistor and a gate of the n-type transistor are coupled to the sum-of-products calculation circuit, and each of the bit signals corresponding to one of the inverters is generated on a common junction point of the p-type transistor and the n-type transistor.

3. The sum-of-products calculation apparatus according to claim 2, wherein the threshold voltages of the inverters are different in response to different channel width-to-length ratios of the p-type transistors and the n-type transistors.

4. The sum-of-products calculation apparatus according to claim 3, wherein channel widths of the p-type transistors of the inverters are identical, and channel widths of the n-type transistors of the inverters are identical.

5. The sum-of-products calculation apparatus according to claim 1, wherein the sum-of-products calculation circuit comprises:
a multiplier, receiving the analog input signals and the weight signals and performing a multiplication calculation on the weight signals and the analog input signals to generate a plurality of product signals; and
an adder, coupled to the multiplier and adding the product signals to generate the analog sum-of-products signal.

6. The sum-of-products calculation apparatus according to claim 5, wherein the adder comprises:
a first comparator, having a positive input terminal receiving the product signals, a negative input terminal coupled to a reference voltage, and an output terminal coupled to input terminals of the inverters; and
a feedback resistor, coupled between the positive input terminal and the output terminal of the first comparator, wherein the output terminal of the first comparator outputs the analog sum-of-products signal.

7. The sum-of-products calculation apparatus according to claim 6, wherein the multiplier comprises:
a plurality of first current sources, respectively controlled by a control voltage and providing a plurality of currents;
a plurality of first switches, coupled to the corresponding first current sources, wherein a state of the first switches is controlled by the analog input signals;
a current mirror circuit, coupled to the first switches, having a plurality of output terminals, and providing a plurality of currents from the output terminals according to the currents provided by the first switches in an on state; and
a plurality of second switches, respectively coupled between corresponding output terminals of the output terminals of the current mirror circuit and the negative input terminal of the first comparator, wherein a state of the second switches is controlled by the weight signals.

8. The sum-of-products calculation apparatus according to claim 7, further comprising:
a control voltage generating circuit, comprising:
a first input inverter, having an input terminal and an output terminal connected to each other and providing a first input voltage, wherein a threshold voltage of the first input inverter is greater than the threshold voltage of any of the inverters;
a second input inverter, having an input terminal and an output terminal connected to each other and providing a second input voltage, wherein a threshold voltage of the second input inverter is less than the threshold voltage of any of the inverters, wherein the second input voltage acting as the reference voltage is provided to the positive input terminal of the first comparator;
a second comparator, having a negative input terminal coupled to the output terminal of the first input inverter;
a transistor, having a control terminal and a first terminal, the control terminal of the transistor being coupled to an output terminal of the second comparator, the first terminal of the transistor being coupled to an operating voltage;
a voltage dividing circuit, coupled to a second terminal of the transistor and a positive input terminal of the second comparator, dividing a voltage at the second terminal of the transistor, and generating a divided voltage to the positive input terminal of the second comparator;
a third comparator, having a positive input terminal and a negative input terminal respectively coupled to the output terminal of the second input inverter and an output terminal of the third comparator, the output terminal of the third comparator being coupled to the voltage dividing circuit; and
a voltage generating circuit, coupled to the control terminal of the transistor and generating the control voltage corresponding to a current flowing through the transistor.

9. The sum-of-products calculation apparatus according to claim 8, wherein the voltage dividing circuit comprises:
a first resistor;
a second resistor, the first resistor and the second resistor being coupled between the second terminal of the transistor and the output terminal of the third comparator, a common junction point of the first resistor and the second resistor being coupled to the positive input terminal of the second comparator.

10. The sum-of-products calculation apparatus according to claim 8, wherein the voltage generating circuit comprises the current mirror circuit.

11. The sum-of-products calculation apparatus according to claim 7, wherein a ratio of current values of the currents provided by the first current sources is a geometric progression, and a ratio of current values of the currents provided by the output terminals of the current mirror circuit is a geometric progression.

12. The sum-of-products calculation apparatus according to claim 1, wherein the encoder circuit encodes the bit signals into the digital signal by referring to a look-up table.

13. The sum-of-products calculation apparatus according to claim 1, wherein the bit signals constitute a thermometer code.

14. The sum-of-products calculation apparatus according to claim 13, wherein the digital signal is a binary signal.

15. The sum-of-products calculation apparatus according to claim 1, the sum-of-products calculation apparatus being an artificial intelligence calculation apparatus or an edge calculation apparatus.
